(19) United States
(12) Patent Application Publication
(10) Pub. No.: US 2014/0166454 A1
(43) Pub. Date: Jun. 19, 2014

(54) SENSING KEYBOARD DEVICE WITH LUMINOUS KEY

(71) Applicant: Primax Electronics Ltd., Neihu (TW)

(72) Inventor: Chung-Yuan Chen, Neihu (TW)

(21) Appl. No.: 13/920,225

(22) Filed: Jun. 18, 2013

(30) Foreign Application Priority Data
Dec. 19, 2012 (TW) 101148408

(51) Int. Cl. H03K 17/96

(52) U.S. Cl. CPC H03K 17/9618
USPC 200/5 A

(57) ABSTRACT

A sensing keyboard device includes at least one luminous key, a non-contact sensor board, at least one light-emitting element, a light guide plate, and a bottom plate. When the non-contact sensor board is triggered by the at least one luminous key, at least one key signal is generated. The at least one light-emitting element is used for emitting at least one light beam. The light guide plate is used for guiding the at least one light beam. An edge of the bottom plate is bent toward the at least one luminous key, and the edge of the bottom plate is near an edge of the light guide plate, so that the at least one light beam is prevented from being leaked out from the edge of the light guide plate.

### FIELD OF THE INVENTION

The present invention relates to a keyboard device, and more particularly to a sensing keyboard device with a luminous key.

### BACKGROUND OF THE INVENTION

Generally, the widely-used peripheral input device of a computer system includes for example a mouse device, a keyboard device, a trackball device, or the like. Via the keyboard device, the user can input characters and symbols into the computer system directly. As a consequence, most users and most manufacturers of input devices pay much attention to the development of keyboard devices.

FIG. 1 is a schematic top view illustrating the outward appearance of a conventional keyboard device. As shown in FIG. 1, there are plural keys 10 on a surface of the conventional keyboard device 1. These keys 10 are classified into several types, e.g. ordinary keys 101, numeric keys 102 and function keys 103. When one of these keys 10 is depressed by the user's finger, a corresponding signal is issued to the computer, and thus the computer executes a function corresponding to the depressed key. For example, when an ordinary key 101 is depressed, a corresponding English letter or symbol is inputted into the computer. When a numeric key 102 is depressed, a corresponding number is inputted into the computer. In addition, the function keys 103 (F1˜F12) can be programmed to provide various functions.

With the maturity of the computing technologies, the conventional keyboard device that has basic functions fails to meet the requirements of various users. For this reason, the keyboard manufacturers make efforts in designing novel keyboard devices with diversified functions. Recently, a conventional keyboard device with a luminous key has been disclosed. The outward appearance of the conventional keyboard device with the luminous key is similar to the outward appearance of the conventional keyboard device 1. Since the keyboard device with the luminous key has the illuminating function, the inner structure of the keyboard device with the luminous key is different from the inner structure of the keyboard device without the luminous key. Hereinafter, the inner structure of the keyboard device with the luminous key will be illustrated in more details. FIG. 2 is a schematic cross-sectional view illustrating a conventional keyboard device with a luminous key. As shown in FIG. 2, the conventional keyboard device 2 comprises plural luminous keys 20, a membrane switch circuit member 21, a light guide plate 22, a backlight module 23, a main circuit board 24, a reflecting plate 25, and a supporting base 26. Each luminous key 20 comprises a keycap 201, a key housing 202, and an elastic element 203. From top to bottom, the keycap 201, the key housing 202, the elastic element 203, the membrane switch circuit member 21, the light guide plate 22, the reflecting plate 25 and the supporting base 26 of the conventional keyboard device 2 are sequentially shown. The backlight module 23 is located at a first side of the membrane switch circuit member 21. The main circuit board 24 is located at a second side of the membrane switch circuit member 21. For example, the conventional keyboard device 2 is a keyboard device for a desktop computer.

In the luminous key 20, the keycap 201 is exposed outside the conventional keyboard device 2, so that the keycap 201 can be depressed by the user. The key housing 202 is used for fixing the keycap 201 and the elastic element 203. The elastic element 203 is penetrated through the key housing 202. In addition, both ends of the elastic element 203 are contacted with the keycap 201 and the membrane switch circuit member 21, respectively. The membrane switch circuit module 21 comprises an upper wiring board 211, a partition plate 212 and a lower wiring board 213. The upper wiring board 211, the partition plate 212 and the lower wiring board 213 are all made of a light-transmissible material. The light-transmissible material includes for example polycarbonate (PC) or polyethylene (PE). The upper wiring board 211 has plural upper contacts 2111. The partition plate 212 is disposed under the upper wiring board 211, and comprises plural perforations 2121 corresponding to the plural upper contacts 2111. The lower wiring board 213 is disposed under the partition plate 212, and comprises plural lower contacts 2131 corresponding to the plural upper contacts 2111. The plural lower contacts 2131 and the plural upper contacts 2111 are collectively defined as plural key intersections. Moreover, the membrane switch circuit module 21 is connected with the main circuit board 24 for transmitting first electric power and signals.

The backlight module 23 comprises an illumination circuit board 231 and plural light-emitting elements 232. For clarification and brevity, only one light-emitting element 232 is shown in the drawing. The illumination circuit board 231 is located at the first side of the membrane switch circuit member 21 for providing second electric power to the plural light emitting diodes 232. The plural light-emitting elements 232 are mounted on the illumination circuit board 231. By acquiring the second electric power, the plural light-emitting elements 232 are driven to emit plural light beams. The plural light-emitting elements 232 are for example side-view light-emitting diodes. The light guide plate 22 is used for guiding the plural light beams to the keycaps 201. As shown in FIG. 2, the reflecting plate 25 is disposed under the light guide plate 22 for reflecting the plural light beams. Moreover, the supporting base plate 26 is disposed under the reflecting plate 25 for supporting the keycap 201, the key housing 202, the elastic element 203, the membrane switch circuit member 21, the light guide plate 22 and the reflecting plate 25.

In the conventional keyboard device 2, the keycap 201 has a light-outputting zone 2011. The light-outputting zone 2011 is located at a character region or a symbol region of the keycap 201. Moreover, the position of the light-outputting zone 2011 is aligned with a light-guiding zone 221 of the light guide plate 22. The light beam can be guided to light-outputting zone 2011 through plural light-guiding dots 221 of the light-guiding zone 221, thereby illuminating the character region or the symbol region of the keycap 201. Consequently, the illuminating function is achieved.

Hereinafter, the inner structure of another conventional keyboard device with a luminous key will be illustrated with reference to FIG. 3. FIG. 3 is a schematic cross-sectional view illustrating another conventional keyboard device with a luminous key. As shown in FIG. 3, the conventional keyboard device 3 comprises plural luminous keys 30, a membrane switch circuit member 31, a backlight module 32, a main circuit board 33, a light guide plate 34, a reflecting plate 35, and a supporting plate 36. Each luminous key 30 comprises a keycap 301, a scissors-type connecting element 302 and an elastic element 303. From top to bottom, the keycap 301, the scissors-type connecting element 302, the elastic element 303, the membrane switch circuit member 31, the light guide plate 34, the reflecting plate 35 and the supporting plate 36 of the conventional keyboard device 3 are sequentially shown. The backlight module 32 is located at a first side of the membrane switch circuit member 31. The main circuit board 33 is located at a second side of the membrane switch circuit member 31. For example, the conventional keyboard device 3 is a keyboard device for a notebook computer. Except that the key housing 202 of the conventional keyboard device 2 is replaced by the scissors-type connecting element 302 of the conventional keyboard device 3, the operations of the other components of the conventional keyboard device 3 are substantially identical to those of the conventional keyboard device 2, and are not redundantly described herein.

On the other hand, as a touch sensing technology with the function of sensing gestures is gradually developed, the touch sensing technology is favored by the manufacturers of various electronic devices. Consequently, the touch sensing technology is applied to various electronic devices, including the keyboard devices. Recently, a keyboard device adopting the touch sensing technology is introduced into the market. However, the touch sensing keyboard device with a luminous key has not been disclosed. Therefore, the manufacturers of various electronic devices make efforts in the integration of a touch sensing keyboard device and a backlight module.

### SUMMARY OF THE INVENTION

The present invention provides a sensing keyboard device with a luminous key.

In accordance with an aspect of the present invention, there is provided a sensing keyboard device. The sensing keyboard device includes at least one luminous key, a non-contact sensor board, at least one light-emitting element, a light guide plate, and a bottom plate. The at least one luminous key is exposed outside a top surface of the sensing keyboard device. The at least one luminous key includes at least one light-outputting zone. The non-contact sensor board is disposed under the at least one luminous key for detecting a depressing action of the at least one luminous key, thereby generating at least one key signal. The at least one light-emitting element is disposed below the at least one luminous key for emitting at least one light beam. The at least one light beam is directed to the at least one light-outputting zone. The light guide plate is disposed under the at least one luminous key for guiding the at least one light beam to the at least one light-outputting zone. The bottom plate is disposed under the light guide plate for supporting the at least one luminous key, the non-contact sensor board and the light guide plate. An edge of the bottom plate is bent toward the at least one luminous key, and the edge of the bottom plate is near an edge of the light guide plate, so that the at least one light beam is prevented from being leaked out from the edge of the light guide plate.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic top view illustrating the outward appearance of a conventional keyboard device;

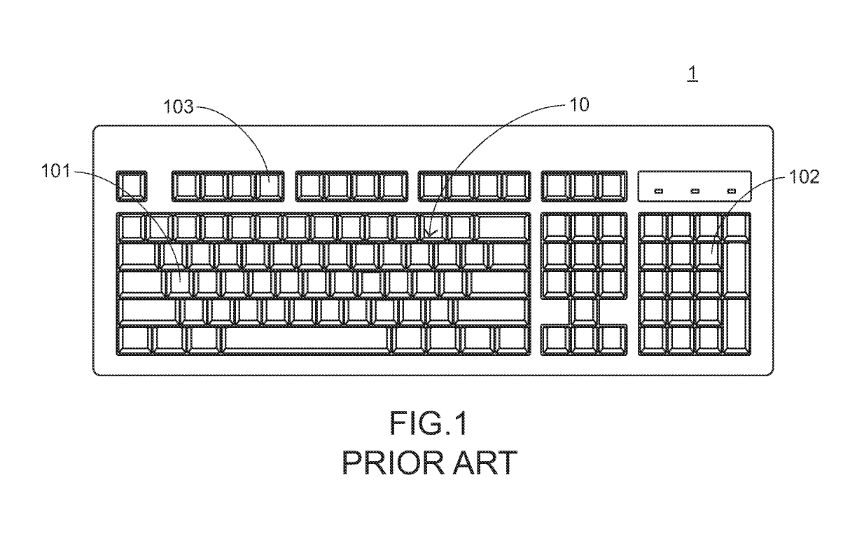

FIG. 2 is a schematic cross-sectional view illustrating a conventional keyboard device with a luminous key;

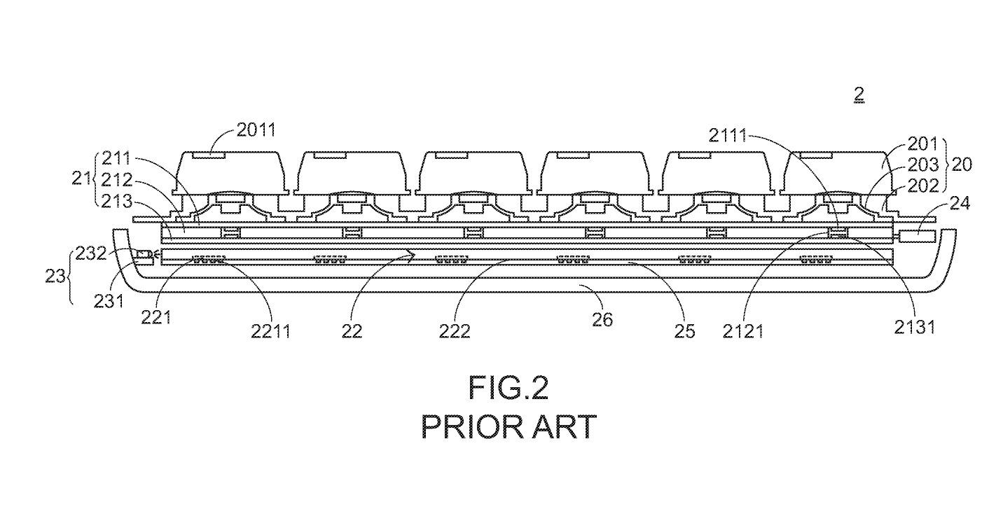

FIG. 3 is a schematic cross-sectional view illustrating another conventional keyboard device with a luminous key;

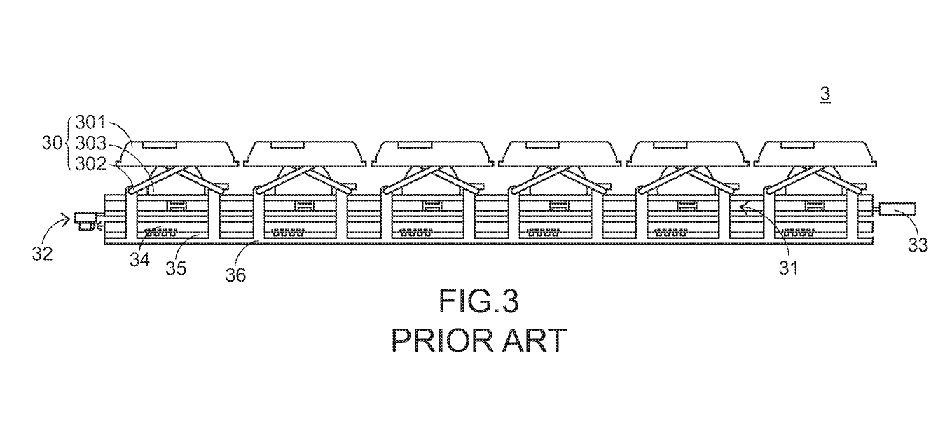

FIG. 4 is a schematic partial exploded view illustrating a sensing keyboard device with a luminous key according to a first embodiment of the present invention;

FIG. 5 is a schematic side view illustrating the sensing keyboard device with a luminous key according to the first embodiment of the present invention;

FIG. 6 is a schematic perspective view illustrating a keycap of the sensing keyboard device with a luminous key according to the first embodiment of the present invention;

FIG. 7 is a schematic partial exploded view illustrating a sensing keyboard device with a luminous key according to a second embodiment of the present invention;

FIG. 8 is a schematic side view illustrating the sensing keyboard device with a luminous key according to the second embodiment of the present invention;

FIG. 9 is a schematic partial exploded view illustrating a sensing keyboard device with a luminous key according to a third embodiment of the present invention;

FIG. 10 is a schematic side view illustrating the sensing keyboard device with a luminous key according to the third embodiment of the present invention;

FIG. 11 is a schematic perspective view illustrating a keycap of the sensing keyboard device with a luminous key according to the third embodiment of the present invention;

FIG. 12 is a schematic partial side view illustrating a sensing keyboard device with a luminous key according to a fourth embodiment of the present invention; and

FIG. 13 is a schematic partial side view illustrating a sensing keyboard device with a luminous key according to a fifth embodiment of the present invention.

### DETAILED DESCRIPTION OF THE PREFERRED EMBODIMENT

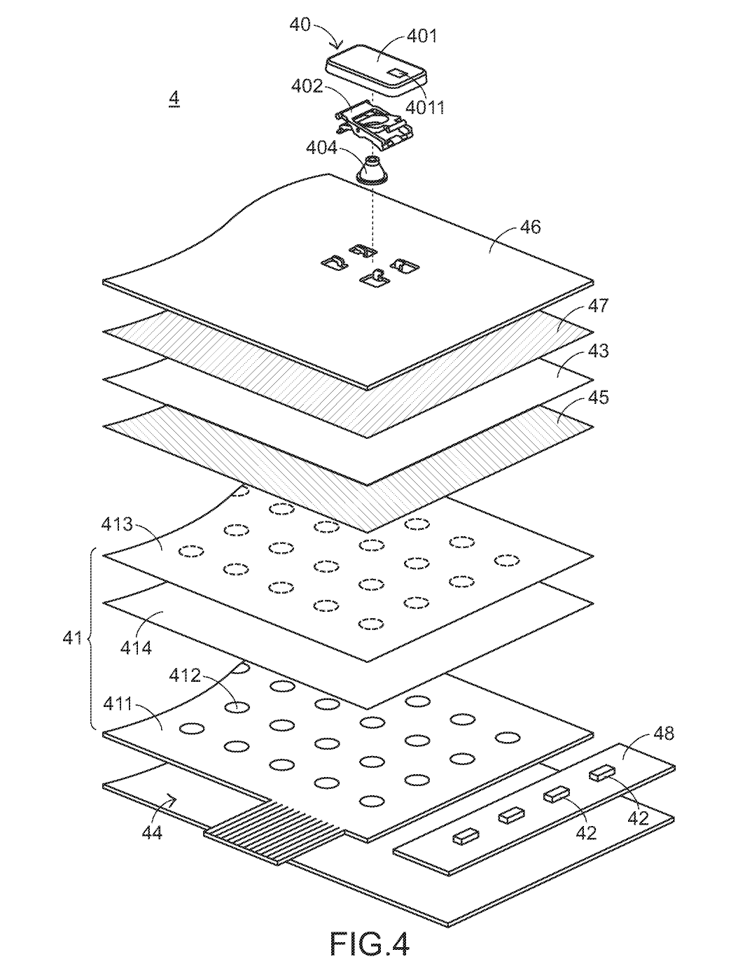

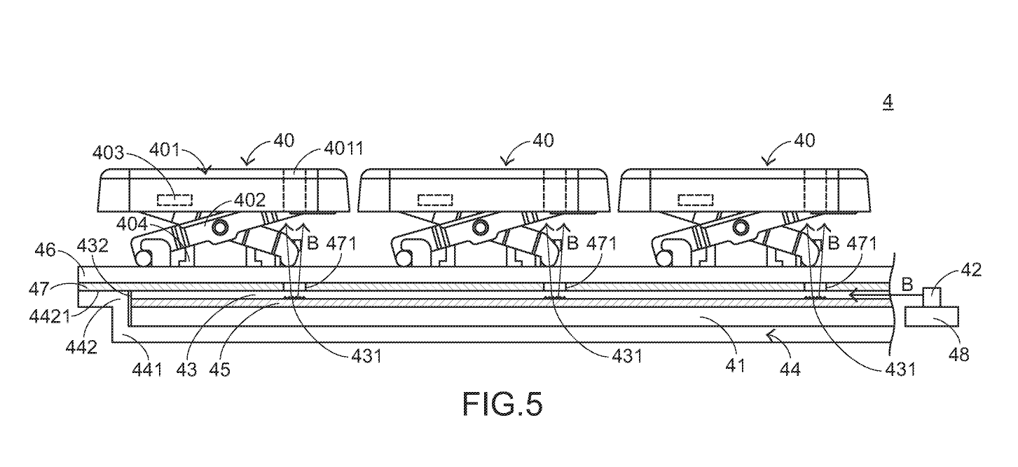

The present invention provides a sensing keyboard device with a luminous key. FIG. 4 is a schematic partial exploded view illustrating a sensing keyboard device with a luminous key according to a first embodiment of the present invention. FIG. 5 is a schematic side view illustrating the sensing keyboard device according to the first embodiment of the present invention. As shown in FIGS. 4 and 5, the sensing keyboard device 4 comprises at least one luminous key 40, a non-contact sensor board 41, at least one light-emitting element 42, a light guide plate 43, a bottom plate 44, a reflecting structure 45, a supporting plate 46, a light-shading plate 47, and a flexible circuit board 48. For clarification and brevity, only one luminous key 40 is shown in FIG. 4. The at least one luminous key 40 is exposed outside a top surface of the sensing keyboard device 4. Each luminous key 40 comprises a keycap 401, a connecting element 402, a conductive element 403, and an elastic element 404. From top to bottom, the keycap 401, the connecting element 402, the elastic element 404, the supporting plate 46, the light-shading plate 47, the light guide plate 43, the reflecting structure 45, the non-contact sensor board 41 and the bottom plate 44 are sequentially shown. The flexible circuit board 48 is located at a side of the non-contact sensor board 41. The at least one light-emitting element 42 is located at a side of the light guide plate 43. The supporting plate 46 is used for supporting the at least one luminous key 40. In this embodiment, the supporting plate 46 is made of a light-transmissible material.

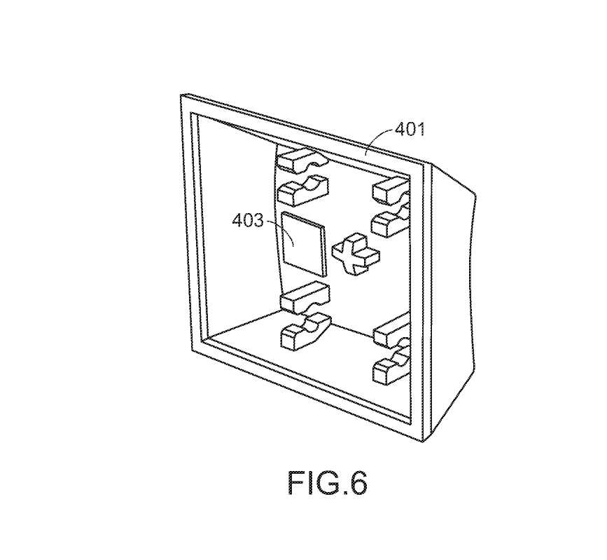

In the luminous key 40, the keycap 401 is exposed outside the top surface of the sensing keyboard device 4. The keycap 401 has at least one light-outputting zone 4011. The connecting element 402 is arranged between the supporting plate 46 and the keycap 401. The connecting element 402 is used for connecting the supporting plate 46 and the keycap 401 and allowing the keycap 401 to be moved upwardly or downwardly relative to the supporting plate 46. The conductive element 403 is disposed on a bottom surface of the keycap 401. In response to the movement of the keycap 401, the non-contact sensor board 41 is correspondingly triggered by the conductive element 403. An example of the conductive element 403 is shown in FIG. 6. The elastic element 404 is arranged between the non-contact sensor board 41 and the keycap 401. Moreover, the elastic element 404 is contacted with the keycap 401 for providing an elastic force to the keycap 401. In response to the elastic force, the keycap 401 is returned to an original position. In this embodiment, each of the at least one light-outputting zone 4011 is a laser-engraved light-transmissible zone with a laser-engraved character or a laser-engraved symbol. The connecting element 402 is a scissors-type connecting element. In this embodiment, the conductive element 403 is a conductive film layer, which is made of conductive foam. The elastic element 404 is made of a light-transmissible rubbery material.

The non-contact sensor board 41 is disposed under the at least one luminous key 40, the supporting plate 46, the light-shading plate 47 and the light guide plate 43 for detecting a depressing action of the at least one luminous key 40, thereby generating at least one key signal. In this embodiment, the non-contact sensor board 41 comprises a substrate 411, a first electrode layer 412, a second electrode layer 413, and a spacer layer 414. The first electrode layer 412 is disposed on a top surface of the substrate 411, and electrically connected to a positive electrode (not shown). The second electrode layer 413 is disposed over the first electrode layer 412, and electrically connected to a negative electrode (not shown). Moreover, the distribution of the electric field between the first electrode layer 412 and the second electrode layer 413 may result in a coupling capacitance. The spacer layer 414 is arranged between the first electrode layer 412 and the second electrode layer 413 for separating the first electrode layer 412 from the second electrode layer 413.

When the keycap 401 of the at least one luminous key 40 is depressed by the user, the keycap 401 is moved relative to the supporting plate 46 and moved to a position near the non-contact sensor board 41. Correspondingly, the conductive element 403 on the bottom surface of the keycap 401 is moved toward the non-contact sensor board 41. Under this circumstance, the distribution of the electric field between the first electrode layer 412 and the second electrode layer 413 is changed by the conductive element 403. That is, a capacitance value between the first electrode layer 412 and the second electrode layer 413 is correspondingly changed. Due to the change of the capacitance value, the non-contact sensor board 41 is triggered to generate a corresponding key signal. In this context, the non-contact sensor board 41 is a touch-sensitive senor board that is enabled in a non-contact manner without the need of forming an electric circuit by the direct contact between adjacent electrode layers. In this embodiment, the non-contact sensor board 41 is a single-layered capacitive sensor board. Moreover, the non-contact sensor board 41 is made of a light-transmissible material. An example of the light-transmissible material includes not limited to polyethylene terephthalate (PET), polycarbonate (PC) or polymethylmethacrylate (PMMA). On the other hand, when the depressing force exerted on the keycap 401 is eliminated, the elastic force provided by the elastic element 404 is acted on the keycap 401. In response to the elastic force, the keycap 401 is returned to an original position.

The flexible circuit board 48 is electrically connected with a main circuit board (not shown) of the sensing keyboard device 4, and located at a side of the non-contact sensor board 41. The flexible circuit board 48 can acquire electric power from the main circuit board. The at least one light-emitting element 42 is disposed below the at least one luminous key 40, and disposed on the flexible circuit board 48. The at least one light-emitting element 42 is used for emitting at least one light beam B. Moreover, the at least one light beam B is directed to the at least one light-outputting zone 4011.

The light guide plate 43 is disposed under the at least one luminous key 40, and located at a side of the at least one light-emitting element 42. The light guide plate 43 comprises plural light-guiding structures 431. The plural light-guiding structures 431 are formed on a bottom surface of the light guide plate 43 for guiding the at least one light beam B to the at least one light-outputting zone 4011. The reflecting structure 45 is arranged between the light guide plate 43 and the non-contact sensor board 41 for reflecting the at least one light beam B. In this embodiment, the light-emitting element 42 is a side-view light-emitting diode, the light-guiding structures 431 are V-cut microstructures, and the reflecting structure 45 is a reflecting plate.

The light-shading plate 47 is disposed over the light guide plate 43 for shading the at least one light beam B. In addition, the light-shading plate 47 has at least one opening 471 for allowing the at least one light beam B to go through. Consequently, the at least one light beam B can be transmitted through the at least one opening 471 and directed to the at least one light-outputting zone 4011. In this embodiment, the light guide plate 43, the reflecting structure 45 and the light-shading plate 47 are disposed over the non-contact sensor board 41. Alternatively, in some other embodiments, the light guide plate, the reflecting structure and the light-shading plate may be disposed under the non-contact sensor board.

The bottom plate 44 is disposed under the light guide plate 43 for supporting the at least one luminous key 40, the non-contact sensor board 41, the supporting plate 46, the light guide plate 43, the light-shading plate 47, the reflecting structure 45 and the flexible circuit board 48. Especially, an edge 441 of the bottom plate 44 is bent toward the at least one luminous key 40, and the edge 441 of the bottom plate 44 is near an edge 432 of the light guide plate 43. Consequently, the at least one light beam B is prevented from being leaked out from the edge 432 of the light guide plate 43. In this embodiment, the bottom plate 44 is a metallic plate. By punching the metallic plate, the edge 441 of the bottom plate 44 is formed as a bent structure 442. Moreover, an upper rim 4421 of the bent structure 442 is at the same level with a top surface of the light guide plate 43. Alternatively, in some other embodiments, the upper rim of the bent structure of the bottom plate is at the same level with the top surface of the non-contact sensor board.

From the above discussions about the sensing keyboard device 4, the non-contact sensor board 41 is triggered to generate a corresponding key signal in response to the depressing action of the keycap 401. Moreover, by means of the at least one light-emitting element 42, the light guide plate 43 and the light-shading plate 47, the at least one light beam B is directed to the at least one light-outputting zone 4011 in order to illuminate the at least one luminous key 40. Moreover, since the bent structure 442 of the bottom plate 44 is near the edge 432 of the light guide plate 43 for shading the at least one light beam B, the possibility of leaking the at least one light beam B from the edge 432 of the light guide plate 43 will be minimized.

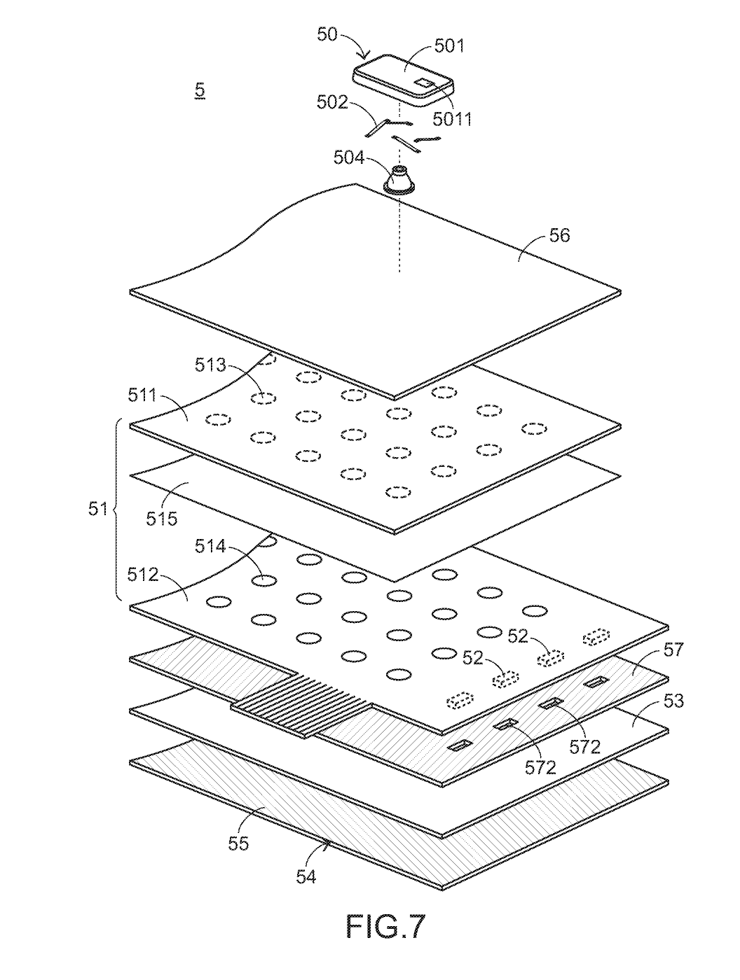

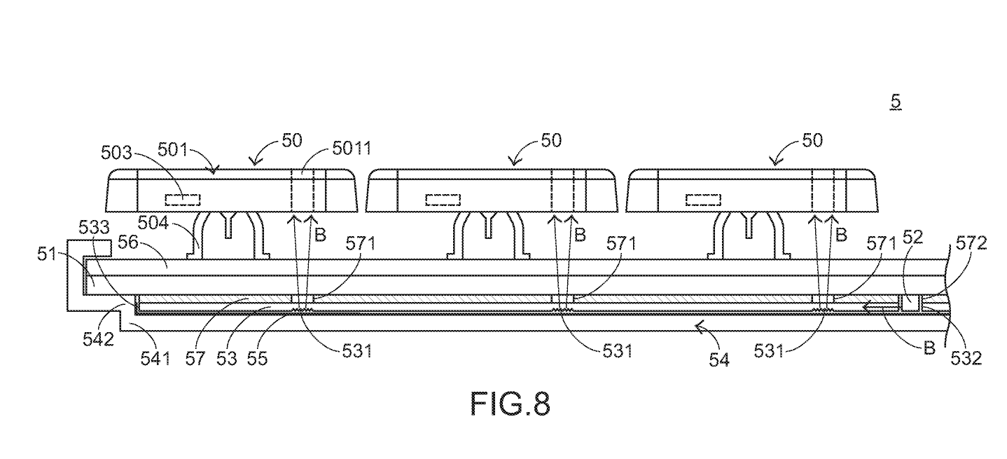

The present invention further provides a sensing keyboard device of a second embodiment. FIG. 7 is a schematic partial exploded view illustrating a sensing keyboard device with a luminous key according to a second embodiment of the present invention. FIG. 8 is a schematic side view illustrating the sensing keyboard device according to the second embodiment of the present invention. As shown in FIGS. 7 and 8, the sensing keyboard device 5 comprises at least one luminous key 50, a non-contact sensor board 51, at least one light-emitting element 52, a light guide plate 53, a bottom plate 54, a reflecting structure 55, a supporting plate 56, and a light-shading plate 57. For clarification and brevity, only one luminous key 50 is shown in FIG. 7. The at least one luminous key 50 is exposed outside a top surface of the sensing keyboard device 5. Each luminous key 50 comprises a keycap 501, a connecting element 502, a conductive element 503, and an elastic element 504. From top to bottom, the keycap 501, the connecting element 502, the elastic element 504, the supporting plate 56, the non-contact sensor board 51, the light-shading plate 57, the reflecting structure 55 and the bottom plate 54 are sequentially shown. The at least one light-emitting element 52 is disposed on a bottom surface of the non-contact sensor board 51. The supporting plate 56 is used for supporting the at least one luminous key 50. In this embodiment, the supporting plate 56 is made of a light-transmissible material.

In the luminous key 50, the keycap 501 is exposed outside the top surface of the sensing keyboard device 5. The keycap 501 has at least one light-outputting zone 5011. The connecting element 502 is arranged between the supporting plate 56 and the keycap 501. The connecting element 502 is used for connecting the supporting plate 56 and the keycap 501 and allowing the keycap 501 to be moved upwardly or downwardly relative to the supporting plate 56. The conductive element 503 is disposed on a bottom surface of the keycap 501. In response to the movement of the keycap 501, the non-contact sensor board 51 is correspondingly triggered by the conductive element 503. The elastic element 504 is arranged between the non-contact sensor board 51 and the keycap 501. Moreover, the elastic element 504 is contacted with the keycap 501 for providing an elastic force to the keycap 501. In response to the elastic force, the keycap 501 is returned to an original position. In this embodiment, each of the at least one light-outputting zone 5011 is a laser-engraved light-transmissible zone with a laser-engraved character or a laser-engraved symbol. The connecting element 502 includes plural resilient arms. In this embodiment, the conductive element 503 is a conductive film layer, which is made of metallic paint. The elastic element 505 is made of a light-transmissible rubbery material.

The non-contact sensor board 51 is disposed under the at least one luminous key 50 for detecting a depressing action of the at least one luminous key 50, thereby generating at least one key signal. In this embodiment, the non-contact sensor board 51 comprises a first substrate 511, a second substrate 512, a first electrode layer 513, a second electrode layer 514, and a spacer layer 515. The first electrode layer 513 is disposed on a bottom surface of the first substrate 511, and electrically connected to a positive electrode (not shown). The second electrode layer 514 is disposed on a top surface of the firs second substrate 512, and electrically connected to a negative electrode (not shown). Moreover, the distribution of the electric field between the first electrode layer 513 and the second electrode layer 514 may result in a coupling capacitance. The spacer layer 515 is arranged between the first electrode layer 513 and the second electrode layer 514 for separating the first electrode layer 513 from the second electrode layer 514. In this embodiment, the non-contact sensor board 51 is a double-layered capacitive sensor board. The non-contact sensor board 51 is made of a light-transmissible material. The operating principles of the non-contact sensor board 51 are similar to those of the non-contact sensor board 41 of the first embodiment, and are not redundantly described herein.

The light guide plate 53 is disposed under the at least one luminous key 50, the supporting plate 56, the non-contact sensor board 51 and the light-shading plate 57. Moreover, the light guide plate 53 comprises plural light-guiding structures 531 and at least one aperture 532. The plural light-guiding structures 531 are formed on a bottom surface of the light guide plate 53 for guiding at least one light beam B to the at least one light-outputting zone 5011. In this embodiment, each of the light-guiding structures 531 is a texturing structure or a light-guiding ink layer.

The light-shading plate 57 is disposed over the light guide plate 53 for shading the at least one light beam B. In addition, the light-shading plate 57 has plural first openings 571 and at least one second opening 572. The plural first openings 571 are aligned with corresponding light-guiding structures 531 for allowing the at least one light beam B to go through. Consequently, the at least one light beam B can be transmitted through the plural first openings 571 and directed to the at least one light-outputting zone 5011. Moreover, the at least one second opening 572 is aligned with the at least one light-emitting element 52.

Please refer to FIGS. 7 and 8 again. The sensing keyboard device 5 of this embodiment is not equipped with a flexible circuit board. The at least one light-emitting element 52 is disposed on the bottom surface of the second substrate 512 of the non-contact sensor board 51. Moreover, the at least one light-emitting element 52 is penetrated through the corresponding second opening 572, and inserted into the corresponding aperture 532 of the light guide plate 53. The at least one light-emitting element 52 is used for emitting the at least one light beam B. The at least one light beam B is introduced into the light guide plate 53, and directed to the at least one light-outputting zone 5011 through the light guide plate 53. In this embodiment, the light-emitting element 52 is a side-view light-emitting diode, and the light guide plate 53 and the light-shading plate 47 are disposed under the non-contact sensor board 51. Alternatively, in some other embodiments, the light guide plate and the light-shading plate may be disposed over the non-contact sensor board.

The bottom plate 54 is disposed under the light guide plate 53 for supporting the at least one luminous key 50, the non-contact sensor board 51, the supporting plate 56, the light guide plate 53 and the light-shading plate 57. Especially, an edge 541 of the bottom plate 54 is bent toward the at least one luminous key 50, and the edge 541 of the bottom plate 54 is near an edge 533 of the light guide plate 53. Consequently, the at least one light beam B is prevented from being leaked out from the edge 533 of the light guide plate 53. The reflecting structure 55 is disposed on a top surface of the bottom plate 54 for reflecting the at least on light beam B. In this embodiment, the bottom plate 54 is a metallic plate. By punching the metallic plate, the edge 541 of the bottom plate 54 is formed as a bent structure 542. In this embodiment, the supporting plate 56 is partially enclosed by the bent structure 542. Moreover, the reflecting structure 55 is a reflective ink layer, which is coated on the top surface of the bottom plate 54 and extended to the edge 541 of the bottom plate 54.

From the above discussions, the sensing keyboard device 5 has the functions similar to the sensing keyboard device 4 of the first embodiment. Since no flexible circuit board is included in the sensing keyboard device 5, the sensing keyboard device 5 has reduced thickness and smaller volume. Since the reflecting structure 55 is extended to the edge 541 of the bottom plate 54, the portion of the at least one light beam B which is leaked out from the edge 533 of the light guide plate 53 will be reflected back to the light guide plate 53 again by the reflecting structure 55. Under this circumstance, the light utilization efficacy is enhanced, and the brightness is increased. Moreover, since the supporting plate 56 is partially enclosed by the bent structure 542 at the edge 541 of the bottom plate 54, during the process of assembling the sensing keyboard device 5, the bent structure 542 can support the light guide plate 53, the reflecting structure 55, the supporting plate 56 and the light-shading plate 57 in order to facilitate alignment and assemblage of various components.

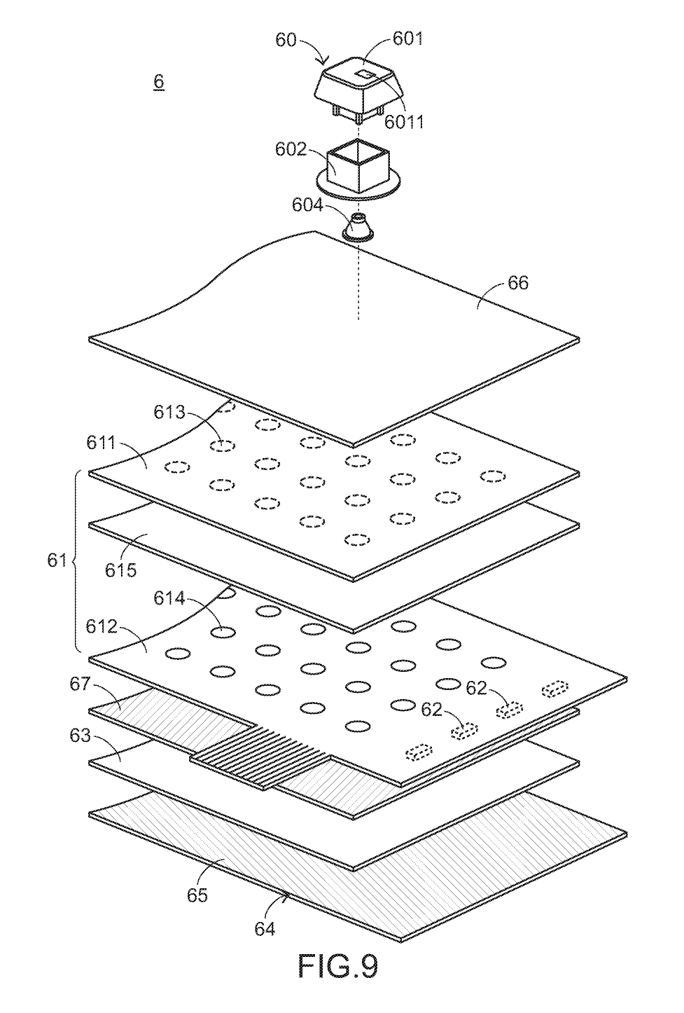

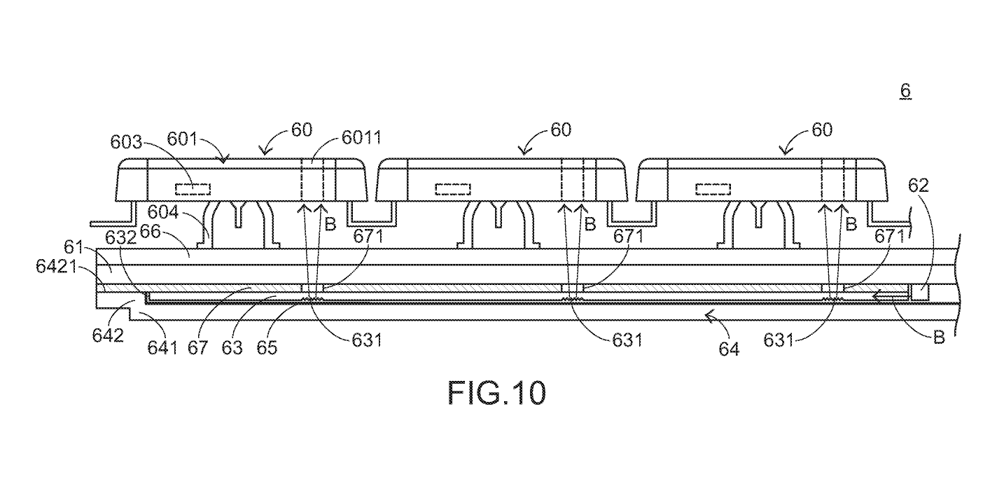

The present invention further provides a sensing keyboard device of a third embodiment. FIG. 9 is a schematic partial exploded view illustrating a sensing keyboard device with a luminous key according to a third embodiment of the present invention. FIG. 10 is a schematic side view illustrating the sensing keyboard device according to the third embodiment of the present invention. As shown in FIGS. 9 and 10, the sensing keyboard device 6 comprises at least one luminous key 60, a non-contact sensor board 61, at least one light-emitting element 62, a light guide plate 63, a bottom plate 64, a reflecting structure 65, a supporting base 66, and a light-shading plate 67. For clarification and brevity, only one luminous key 60 is shown in FIG. 9. Except for the following three items, the structures of the sensing keyboard device 6 of this embodiment are substantially identical to those of the sensing keyboard device 5 of the second embodiment, and are not redundantly described herein.

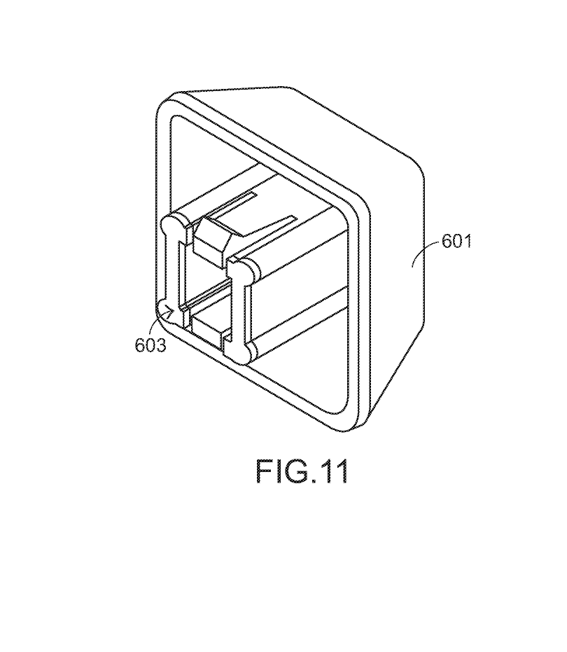

Firstly, the supporting base 66 is used for supporting the at least one luminous key 60. The at least one luminous key 60 is exposed outside a top surface of the sensing keyboard device 6. Each luminous key 60 comprises a keycap 601, a key housing 602, a conductive element 603, and an elastic element 604. The keycap 601 is exposed outside the top surface of the sensing keyboard device 6. The key housing 602 is arranged between the supporting base 66 and the keycap 601 for supporting the keycap 601. The conductive element 603 is disposed on a bottom surface of the keycap 601. In response to the movement of the keycap 601, the non-contact sensor board 61 is correspondingly triggered by the conductive element 603. An example of the conductive element 603 is shown in FIG. 11. The elastic element 604 is penetrated through the key housing 602, and arranged between the non-contact sensor board 61 and the keycap 601. Moreover, the elastic element 604 is contacted with the keycap 601 for providing an elastic force to the keycap 601. In response to the elastic force, the keycap 601 is returned to an original position. In this embodiment, the supporting base 66 is made of a light-transmissible material, and each of the at least one light-outputting zone 6011 is a laser-engraved light-transmissible zone with a laser-engraved character or a laser-engraved symbol. In this embodiment, the conductive element 603 is a conductive film layer, which is made of conductive foam. The elastic element 604 is made of a light-transmissible rubbery material.

Secondly, the non-contact sensor board 61 is disposed under the at least one luminous key 60 for detecting a depressing action of the at least one luminous key 60, thereby generating at least one key signal. In this embodiment, the non-contact sensor board 61 comprises a first substrate 611, a second substrate 612, a first electrode layer 613, a second electrode layer 614, and a partition plate 615. The first electrode layer 613 is disposed on a bottom surface of the first substrate 611, and electrically connected to a positive electrode (not shown). The second electrode layer 614 is disposed on a top surface of the second substrate 612, and electrically connected to a negative electrode (not shown). Moreover, the distribution of the electric field between the first electrode layer 613 and the second electrode layer 614 may result in a coupling capacitance. The partition plate 615 is arranged between the first electrode layer 613 and the second electrode layer 614 for separating the first electrode layer 613 from the second electrode layer 614. In this embodiment, the non-contact sensor board 61 is a triple-layered capacitive sensor board. The non-contact sensor board 61 is made of a light-transmissible material. The operating principles of the non-contact sensor board 61 are similar to those of the non-contact sensor board 41 of the first embodiment, and are not redundantly described herein.

Thirdly, the bottom plate 64 is disposed under the light guide plate 63 for supporting the at least one luminous key 60, the non-contact sensor board 61, the supporting base 66, the light guide plate 63 and the light-shading plate 67. Especially, an edge 641 of the bottom plate 64 is bent toward the at least one luminous key 60, and the edge 641 of the bottom plate 64 is near an edge 632 of the light guide plate 63. Consequently, the at least one light beam B emitted by the at least one light-emitting element 62 is prevented from being leaked out from the edge 632 of the light guide plate 63. In this embodiment, the bottom plate 64 is a metallic plate. By punching the metallic plate, the edge 641 of the bottom plate 64 is formed as a bent structure 642. Moreover, an upper rim 6421 of the bent structure 642 is at the same level with a top surface of the light guide plate 63. Alternatively, in some other embodiments, the upper rim of the bent structure of the bottom plate is at the same level with the top surface of the non-contact sensor board.

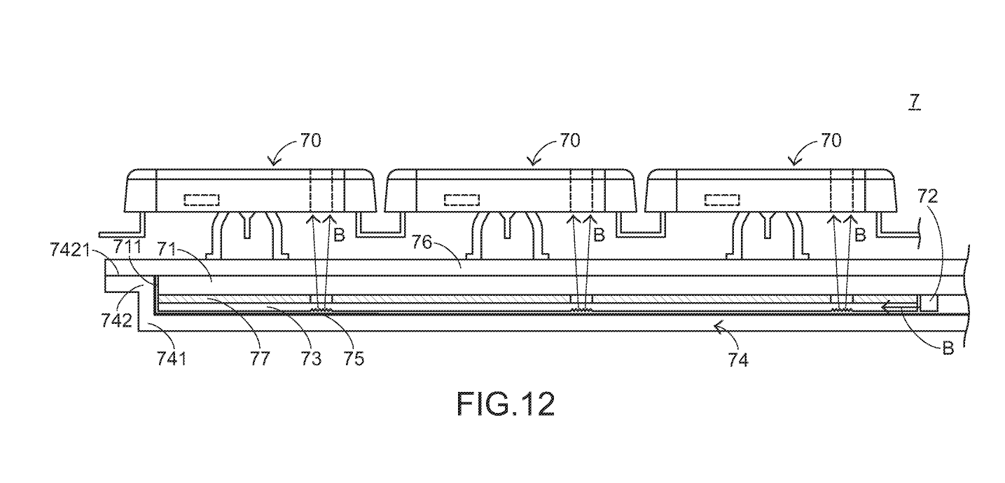

The present invention further provides a sensing keyboard device of a fourth embodiment. FIG. 12 is a schematic partial side view illustrating a sensing keyboard device with a luminous key according to a fourth embodiment of the present invention. As shown in FIG. 12, the sensing keyboard device 7 comprises at least one luminous key 70, a non-contact sensor board 71, at least one light-emitting element 72, a light guide plate 73, a bottom plate 74, a reflecting structure 75, a supporting base 76, and a light-shading plate 77. Except for the following two items, the structures of the sensing keyboard device 7 of this embodiment are substantially identical to those of the sensing keyboard device 6 of the third embodiment, and are not redundantly described herein.

Firstly, the bottom plate 74 is disposed under the light guide plate 73 for supporting the at least one luminous key 70, the non-contact sensor board 71, the supporting base 76, the light guide plate 73 and the light-shading plate 77. Especially, an edge 741 of the bottom plate 74 is bent toward the at least one luminous key 70, and the edge 741 of the bottom plate 74 is near an edge 711 of the non-contact sensor board 71. Consequently, at least one light beam B emitted by the at least one light-emitting element 72 is prevented from being leaked out from the edge 711 of the non-contact sensor board 71. In this embodiment, the bottom plate 74 is a metallic plate. By punching the metallic plate, the edge 741 of the bottom plate 74 is formed as a bent structure 742. Moreover, an upper rim 7421 of the bent structure 742 is at the same level with a top surface of the non-contact sensor board 71. Secondly, the reflecting structure 75 is disposed on a top surface of the bottom plate 74 for reflecting the at least one light beam B. The reflecting structure 75 is a reflective ink layer, which is coated on a top surface of the bottom plate 74 and extended to the edge 711 of the non-contact sensor board 71.

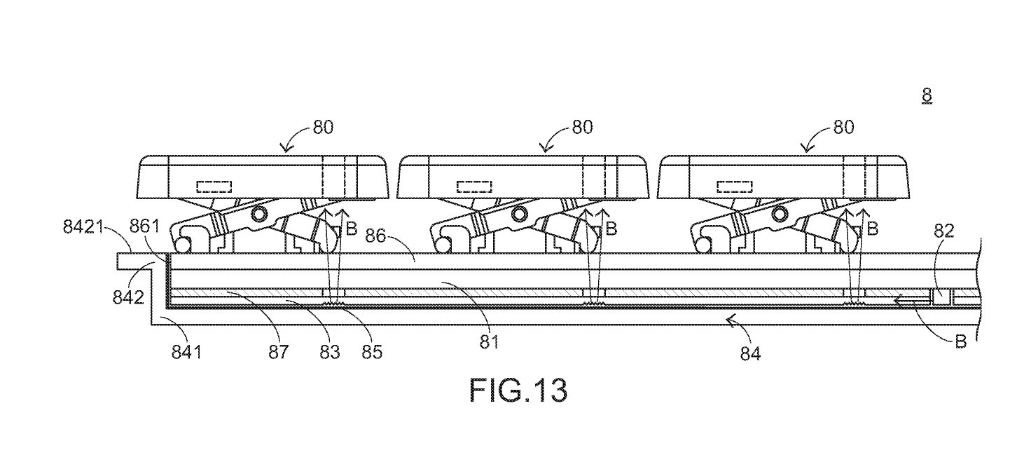

The present invention further provides a sensing keyboard device of a fifth embodiment. FIG. 13 is a schematic partial side view illustrating a sensing keyboard device with a luminous key according to a fifth embodiment of the present invention. As shown in FIG. 13, the sensing keyboard device 8 comprises at least one luminous key 80, a non-contact sensor board 81, at least one light-emitting element 82, a light guide plate 83, a bottom plate 84, a reflecting structure 85, a supporting plate 86, and a light-shading plate 87. The structures of the at least one luminous key 80 and the supporting plate 86 of the sensing keyboard device 8 of this embodiment are substantially identical to those of the sensing keyboard device 4 of the first embodiment, and are not redundantly described herein. The structures of the non-contact sensor board 81, the at least one light-emitting element 82, the light guide plate 83, the bottom plate 84, the reflecting structure 85 and the light-shading plate 87 of the sensing keyboard device 8 of this embodiment are substantially identical to those of the sensing keyboard device 5 of the second embodiment, and are not redundantly described herein.

In comparison with the sensing keyboard device 4 and the sensing keyboard device 5, two items of the sensing keyboard device 8 of this embodiment are distinguished. Firstly, the bottom plate 84 is disposed under the light guide plate 83 for supporting the at least one luminous key 80, the non-contact sensor board 81, the supporting base 86, the light guide plate 83 and the light-shading plate 87. Especially, an edge 841 of the bottom plate 84 is bent toward the at least one luminous key 80, and the edge 841 of the bottom plate 84 is near an edge 861 of the supporting base 86. Consequently, at least one light beam B emitted by the at least one light-emitting element 82 is prevented from being leaked out from the edge 861 of the supporting base 86. In this embodiment, the bottom plate 84 is a metallic plate. By punching the metallic plate, the edge 841 of the bottom plate 84 is formed as a bent structure 842. Moreover, an upper rim 8421 of the bent structure 842 is at the same level with a top surface of the supporting base 86. Secondly, the reflecting structure 85 is disposed on a top surface of the bottom plate 84 for reflecting the at least one light beam B. The reflecting structure 85 is a reflective ink layer, which is coated on a top surface of the bottom plate 84 and extended to the edge 861 of the supporting base 86.

From the above descriptions, the present invention provides a sensing keyboard device with a luminous key. The sensing keyboard device utilizes the non-contact sensor board to generate a key signal. Moreover, by means of the at least one light-emitting element, the light guide plate and the light-shading plate, the at least one light beam is directed to the at least one light-outputting zone in order to illuminate the laser-engraved character or the laser-engraved symbol of the keycap. Moreover, since the edge of the bottom plate is punched as the bent structure and the light beam leaked out from the edge of the light guide plate is shaded by the bent structure, the problem of leaking the light beam will be overcome.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A sensing keyboard device, comprising:
at least one luminous key exposed outside a top surface of said sensing keyboard device, wherein said at least one luminous key comprises at least one light-outputting zone;
a non-contact sensor board disposed under said at least one luminous key for detecting a depressing action of said at least one luminous key, thereby generating at least one key signal;
at least one light-emitting element disposed below said at least one luminous key for emitting at least one light beam, wherein said at least one light beam is directed to said at least one light-outputting zone;
a light guide plate disposed under said at least one luminous key for guiding said at least one light beam to said at least one light-outputting zone; and
a bottom plate disposed under said light guide plate for supporting said at least one luminous key, said non-contact sensor board and said light guide plate, wherein an edge of said bottom plate is bent toward said at least one luminous key, and said edge of said bottom plate is near an edge of said light guide plate, so that said at least one light beam is prevented from being leaked out from said edge of said light guide plate.

2. The sensing keyboard device according to claim 1, wherein said edge of said bottom plate is punched as a bent structure, wherein an upper rim of said bent structure is at the same level with a top surface of said light guide plate.

3. The sensing keyboard device according to claim 1, wherein said edge of said bottom plate is punched as a bent structure, wherein an upper rim of said bent structure is at the same level with a top surface of said non-contact sensor board.

4. The sensing keyboard device according to claim 1, further comprising a supporting plate for supporting said at least one luminous key, wherein said at least one luminous key comprises:
a keycap exposed outside said top surface of said sensing keyboard device, wherein said at least one light-outputting zone is formed on said keycap;
a connecting element arranged between said supporting plate and said keycap for connecting said supporting plate and said keycap and allowing said keycap to be moved upwardly or downwardly relative to said supporting plate;
a conductive element disposed on a bottom surface of said keycap, wherein in response to a movement of said keycap, said non-contact sensor board is correspondingly triggered by said conductive element; and
an elastic element arranged between said non-contact sensor board and said keycap for providing an elastic force to said keycap, wherein said keycap is returned to an original position in response to said elastic force.

5. The sensing keyboard device according to claim 4, wherein said edge of said bottom plate is punched as a bent structure, wherein said supporting plate is partially enclosed by said bent structure.

6. The sensing keyboard device according to claim 4, wherein said edge of said bottom plate is punched as a bent structure, wherein an upper rim of said bent structure is at the same level with a top surface of said supporting plate.

7. The sensing keyboard device according to claim 1, further comprising a supporting base for supporting said at least one luminous key, wherein said at least one luminous key comprises:
a keycap exposed outside said top surface of said sensing keyboard device, wherein said at least one light-outputting zone is formed on said keycap;
a key housing arranged between said supporting base and said keycap for supporting said keycap;
a conductive element disposed on a bottom surface of said keycap, wherein in response to a movement of said keycap, said non-contact sensor board is correspondingly triggered by said conductive element; and
an elastic element penetrated through said key housing and arranged between said non-contact sensor board and said keycap for providing an elastic force to said keycap, wherein said keycap is returned to an original position in response to said elastic force.

8. The sensing keyboard device according to claim 7, wherein said edge of said bottom plate is punched as a bent structure, wherein said supporting base is partially enclosed by said bent structure.

9. The sensing keyboard device according to claim 1, further comprising a light-shading plate, wherein said light-shading plate is disposed over said light guide plate for shading said at least one light beam, and said light-shading plate has at least one opening for allowing said at least one light beam to go through, so that said at least one light beam is transmitted through said at least one opening and directed to said at least one light-outputting zone.

10. The sensing keyboard device according to claim 1, wherein said non-contact sensor board is made of a light-transmissible material, wherein said light-transmissible material includes but is not limited to polyethylene terephthalate (PET), polycarbonate (PC) or polymethylmethacrylate (PMMA).

11. The sensing keyboard device according to claim 1, further comprising a flexible circuit board, wherein said at least one light-emitting element is disposed on said flexible circuit board, and said light-emitting element is a side-view light-emitting diode.

12. The sensing keyboard device according to claim 1, wherein said at least one light-emitting element is disposed on a bottom surface of said non-contact sensor board, and said light-emitting element is a side-view light-emitting diode.

13. The sensing keyboard device according to claim 1, wherein said light guide plate comprises plural light-guiding structures, wherein said plural light-guiding structures are formed on a bottom surface of said light guide plate for guiding said at least one light beam to said at least one light-outputting zone, wherein each of said light-guiding structures is a V-cut microstructure, a texturing structure or a light-guiding ink layer.

14. The sensing keyboard device according to claim 1, further comprising a reflecting structure, wherein said reflecting structure is arranged between said light guide plate and said bottom plate for reflecting said at least one light beam, wherein said reflecting structure is a reflecting plate, or said reflecting structure is a reflective ink layer coated on a top surface of said bottom plate.

15. The sensing keyboard device according to claim 1, wherein said non-contact sensor board comprises:
a substrate;
a first electrode layer disposed on a surface of said substrate;
a second electrode layer disposed over said first electrode layer; and
a spacer layer arranged between said first electrode layer and said second electrode layer for separating said first electrode layer from said second electrode layer.

16. The sensing keyboard device according to claim 1, wherein said non-contact sensor board comprises:
a first substrate;
a second substrate;
a first electrode layer disposed on a bottom surface of said first substrate;
a second electrode layer disposed on a top surface of said second substrate; and
a spacer layer arranged between said first electrode layer and said second electrode layer for separating said first electrode layer from said second electrode layer.

17. The sensing keyboard device according to claim 1, wherein said non-contact sensor board comprises:
a first substrate;
a second substrate;
a first electrode layer disposed on a bottom surface of said first substrate;
a second electrode layer disposed on a top surface of said second substrate; and
a partition plate arranged between said first electrode layer and said second electrode layer for separating said first electrode layer from said second electrode layer.
